(19) United States
(12) Patent Application Publication
(10) Pub. No.: US 2007/0108043 A1
(43) Pub. Date: May 17, 2007

(54) Sputtering target including titanium silicon oxide and method of making coated article using the same

(75) Inventor: Yiwei Lu, Ann Arbor, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/272,448

(22) Filed: Nov. 14, 2005

(51) Int. Cl. C23C 14/00

(52) U.S. Cl. 204/192.15; 204/298.13

(57) ABSTRACT

This invention relates to a sputtering target of or including Ti₁₋ₓSiₓO_{y} and/or a method of making a coated article using such a sputtering target. In certain example embodiments, the Ti₁₋ₓSiₓO_{y} may be substoichiometric with respect to oxygen. In certain example embodiments of this invention, the target may include Ti₁₋ₓSiₓO_{y} where x is from about 0.05 to 0.95 (more preferably from about 0.1 to 0.9, and even more preferably from about 0.2 to 0.8, and possibly from about 0.5 to 0.8) and y is from about 0.2 to 1.95 (more preferably from about 0.2 to 1.95, and even more preferably from about 0.2 to 1.90, and possibly from about 1.0 to 1.85). The sputtering target may be sputtered in an atmosphere of or including one or more of Ar, O₂ and/or N₂ gas(es) in certain example embodiments of this invention.

This invention relates to a sputtering target of or including Ti₁₋ₓSiₓO_{y} and/or a method of making a coated article using such a sputtering target. In certain example embodiments, the target can be a ceramic target. In certain example embodiments, the Ti₁₋ₓSiₓO_{y} may be substoichiometric with respect to oxygen. In certain example embodiments of this invention, the target may be of or include Ti₁₋ₓSₓO_{y} where x is from about 0.05 to 0.95 (more preferably from about 0.1 to 0.9, and even more preferably from about 0.2 to 0.8, and possibly from about 0.5 to 0.8) and y is from about 0.2 to 1.95 (more preferably from about 0.2 to 1.95, and even more preferably from about 0.2 to 1.90, and possibly from about 1.0 to 1.85). The sputtering target may be sputtered in an atmosphere of or including one or more of Ar, O₂ and/or N₂ gas(es) in certain example embodiments of this invention.

### BACKGROUND OF THE INVENTION

Sputtering is known in the art as a technique for depositing layer(s) or coating(s) onto substrates. For example, antireflective (AR) and/or low-emissivity (low-E) coatings can be deposited onto a glass substrate by successively sputter-depositing one or more different layers onto the substrate. As an example, a low-E coating may include the following layers in this order: glass substrate/SnO₂/ZnO/Ag/ZnO, where the Ag layer is an IR reflecting layer and the metal oxide layers are dielectric layers. In this example, one or more tin (Sn) targets may be used to sputter-deposit the base layer of SnO₂, one or more zinc (Zn) inclusive targets may be used to sputter-deposit the next layer of ZnO, an Ag target may be used to sputter-deposit the Ag layer, and so forth. As another example, a Ti or TiOₓ target may be used to sputter-deposit a layer of titanium oxide (e.g., TiOₓ) on a substrate as a base layer or as some other layer in the stack in certain instances. The sputtering of each target is performed in a chamber housing a gaseous atmosphere (e.g., a mixture of Ar and O gases in the Sn, Ti and/or Zn target atmosphere(s)). In each sputtering chamber, sputtering gas discharge is maintained at a partial pressure less than atmospheric.

Example references discussing sputtering and devices used therefore include U.S. Pat. Nos. 5,427,665, 5,725,746, 6,743,343, and 2004/0163943, the entire disclosures of which are all hereby incorporated herein by reference.

A sputtering target (e.g., cylindrical rotatable magnetron sputtering target) typically includes a cathode tube within which is a magnet array. The cathode tube is often made of stainless steel or some other conductive material. The target material is formed on the tube by spraying, casting or pressing it onto the outer surface of the stainless steel cathode tube (optionally, a backing layer may be provided between the cathode tube and the target material layer). Each sputtering chamber includes one or more targets, and thus includes one or more of these cathode tubes. The cathode tube(s) may be held at a negative potential (e.g., −200 to −1500 V), and may be sputtered when rotating. Due to the negative biased potential on a target, ions from the sputtering gas discharge are accelerated into the target and dislodge, or sputter off, atoms of the target material. These atoms, in turn, together with the gas form the appropriate compound (e.g., tin oxide) that is directed to the substrate in order to form a thin film or layer of the same on the substrate.

There are different types of sputtering targets, such as planar magnetron and cylindrical rotatable magnetron targets. Planar magnetrons may have an array of magnets arranged in the form of a closed loop and mounted in a fixed position behind the target. A magnetic field in the formed of a closed loop is thus formed in front of the target. This field causes electrons from the discharge to be trapped in the field and travel in a pattern which creates a more intense ionization and higher sputtering rate.

In the case of rotating magnetron sputtering targets, the cathode tube and target material thereon are rotated over a magnetic array (that is often stationary) that defines the sputtering zone. Due to the rotation, different portions of the target are continually presented to the sputtering zone which results in a fairly uniform sputtering of the target material off of the tube.

Materials such as tin oxide, zinc oxide, and silicon nitride have an index of refraction (n) around 2, where SiO₂ has an index of refraction (n) of about 1.5 and TiO₂ has an index of refraction of about 2.4. There exists a need for materials, that can be used in low-E and/or AR coatings, that have an index of refraction (n) between these values (e.g., from about 1.6 to 1.9, or 2.1 to 2.3). Materials with such index values would be advantageous in that they could be used to further reduce reflection in coated articles using low-E and/or AR coatings having the same. Alloys, mixes of reactive gases, or combinations of both alloys and mixtures of reactive gases are used to generate thin films having desired properties that cannot be achieved using a single elemental metal approach, or a pure oxide approach.

The approach of using alloy metals as metal sputtering targets is limited by achievable small ranges of solid solution that restrict the ratio amount different materials. Metallic alloy metal targets also face low deposition rate problems in reactive sputtering when full oxide and/or nitride films are desired.

The approach of mixing gases when sputtering metal or Si targets is also problematic. Silicon and aluminum oxynitride can be tailored to obtain index values from 1.6 to 1.9. However, unfortunately, the conventional way of doing this is to use a Si or Al target and vary the gas flows of nitrogen and oxygen to gain the desired oxygen to nitrogen ratio in the resulting layer to adjust its index of refraction value. It is difficult to consistently adjust oxygen/nitrogen stoichiometry in the resulting layer in a desired manner by adjusting oxygen and nitrogen gas flows using a Si or Al target. Oxygen and nitrogen gases have different weights and it is difficult to get consistent predictable results by varying oxygen and nitrogen gas flows when using a Si target in sputtering silicon oxynitride. Moreover, silicon or aluminum oxynitride is also disadvantageous in that its potential index range is limited to only from about 1.5 or 1.6 to 2.0 (at 550 nm) for fully oxynitrided films without absorption loss in the visible.

In view of the above, it will be appreciated that there exists a need in the art for an improved technique to consistently form sputter-deposited layers having an index of refraction (n) in the range of from about 1.6 to 2.4, and sometimes from about 1.6 to 1.9. In particular, there exists a need for a technique which permits layers to be formed in a manner which allows a desired refraction index value in this range to be consistently achievable.

### BRIEF SUMMARY OF EXAMPLE EMBODIMENTS OF THE INVENTION

Certain example embodiments of this invention relate to a sputtering target of or including Ti₁₋ₓSiₓO_{y} and/or a method of making a coated article using such a sputtering target. In certain example embodiments, the target may be a rotatable magnetron sputtering target, a stationary planar target, or the like. In certain example embodiments, the Ti₁₋ₓSiₓO_{y} may be substoichiometric with respect to oxygen. In certain example embodiments of this invention, the target may be of or include Ti₁₋ₓSiₓO_{y} where x is from about 0.05 to 0.95 (more preferably from about 0.1 to 0.9, and even more preferably from about 0.2 to 0.8, and possibly from about 0.5 to 0.8) and y is from about 0.2 to 1.95 (more preferably from about 0.2 to 1.95, and even more preferably from about 0.2 to 1.90, and possibly from about 1.0 to 1.85). The sputtering target may be sputtered in an atmosphere of or including one or more of Ar, O₂ and/or N₂ gas(es) in certain example embodiments of this invention. Other materials may be provided in the target in alternative example embodiments of this invention.

Such a target may be used to permit layers with tunable indices of refraction (n) to be consistently achieved by sputter deposition. By adjusting the Ti and Si amounts in the target (e.g., the Ti/Si ratio in the target itself), layers of or including TiSiOₓ (e.g., where x is from about 1.5 to 2.0) can be formed by sputter-deposition and can achieve consist desired index values (n). For example, the more Si in the target, the lower the index of refraction (n) value of the resulting sputter-deposited layer. Likewise, the more Ti in the target (and thus the less Si), the higher the index of refraction (n) value of the resulting sputter-deposited layer. Thus, an improved technique is provided to consistently form sputter-deposited thin film layers having an index of refraction (n) in the range of from about 1.6 to 2.4, or sometimes from about 1.6 to 1.9. In particular, a technique is provided which permits layers to be sputter-deposited in a manner which allows a desired refraction index (n) value in this range to be consistently achievable. While gas flows may be adjusted to alter or tailor the index (n) value of the resulting layer, the primary way to adjust the index (n) value of the resulting layer is to adjust the Ti/Si ratio in the target itself.

The combination of Ti and Si in the target is advantageous in that Si and Ti form a suitable alloy. Since a ceramic target is used, including Ti and Si, the amounts of Ti and Si can be varied to allow the desired index (n) value to be obtained in the resulting layer. Moreover, the ceramic nature of the sputtering target is advantageous in that it permits higher sputtering rates to be achieved. The oxygen in the target is substoichiometric in certain example embodiments of this invention.

In certain example embodiments of this invention, there is provided a target for use in sputter depositing a layer(s) on a substrate, the target comprising a target material comprising titanium, silicon and oxygen, so as to be a ceramic target. The target may be a rotatable magnetron sputtering target, a planar target, or the like in different instances.

In certain example embodiments of this invention, there is provided a target for use in sputter depositing a layer(s) on a substrate, the target comprising a target material comprising Ti₁₋ₓSiₓO_{y} where x is from about 0.05 to 0.95 and y is from about 0.2 to 1.95.

In still further example embodiments of this invention, there is provided a method of sputter-depositing a layer comprising silicon oxide and titanium oxide on a substrate, the method comprising: providing a target comprising Ti₁₋ₓSiₓO_{y} where x is from about 0.05 to 0.95 and y is from about 0.2 to 1.95, and flowing argon and/or oxygen gas in a chamber where the target is located, so as to cause the layer comprising silicon oxide and titanium oxide to be formed on the substrate.

### BRIEF DESCRIPTION OF THE DRAWINGS

FIG. 1 is a cross sectional view of a sputtering target according to an example embodiment of this invention, being used in sputter-depositing a layer on a substrate.

FIG. 2 is a graph illustrating optical properties (n and k) of Ti₁₋ₓSiₓO₂ thin film layers according to example embodiments of this invention (compared to TiO₂ and SiO₂ thin film layers).

FIG. 3 is a graph illustrating refractive index (n) values at 550 nm of thin film Ti₁₋ₓSiₓO₂ layers, as a function of different x values, showing that the index value (n) of the resulting sputter-deposited layer can be adjusted or tailored by adjusting the Ti/Si ratio in the target (i.e., by adjusting x in the target).

FIG. 4 is a graph illustrating optical properties (n and k) of thin film layers of Ti₁₋ₓSiₓO_{2-y}N_{y} (where x=0.75) according to example embodiments of this invention, as a function of adjusting the oxygen and nitrogen gas flows used when sputtering the layer (at the different N₂/O₂ ratios of 0, 3 and 7); illustrating that the increase of nitrogen gas in the sputtering process results in an increased index of refraction (n) value and absorption due to the increase in silicon nitride and titanium nitride in the resulting thin film layer.

FIG. 5 is a graph illustrating optical properties (n and k) of thin film layers of Ti₁₋ₓSiₓO_{2-y}N_{y} (using a N₂/O₂ gas flow ratio of 0.48 during sputtering), with varying x values; the figure illustrate that decreasing x results in an increase in refractive index (n) values and absorption due to an increase in titanium oxide and titanium nitride in the thin film layer.

FIG. 6 is a graph illustrating the reflection %, as a function of wavelength, of coated article including a 3-layered AR coating on both sides of a 5 mm thick float glass substrate (soda lime silica glass) (compared to reflection % of an uncoated 5 mm thick similar glass substrate), according to an example embodiment of this invention.

### DETAILED DESCRIPTION OF EXAMPLE EMBODIMENTS OF THE INVENTION

Performance of optical coatings such as low-E and/or antireflective (AR) coatings, especially multi-layered coatings for broadband applications, relies on precisely controlled layer thicknesses and optical properties (e.g., n and/or k) in each individual layer in the coating(s). Materials having unique properties, such as refractive index (n) and extinction coefficient (k), stress and adhesion to adjacent layers are chosen to optimize the coating performance with respect to reflection, color, durability, and/or the like. The target may be a rotating magnetron sputtering target in certain example embodiments although other types of target are also possible in other alternative embodiments. For example, a non-rotating target may be used instead and applicable to this invention. As an example, a drum coater may be designed in such a way that neither the target nor the drum holding the substrate rotates, but instead magnets in the target tube rotate.

Certain example embodiments of this invention relate to optical coating fabricating using sputtering target(s) of or including Ti₁₋ₓSiₓO_{y}. Such targets can be fabricated into either planar or rotating magnetron targets in different example embodiments of this invention. The use of Ti₁₋ₓSiₓO_{y} as a target material permits sputtering targets to be made which can be used to sputter-deposit thin film layers with consistent and predictable optical properties (e.g., n and/or k), covering a large potential index of refraction (n) range and allowing excellent repeatability because the Ti/Si ratio in the target is pre-defined and fairly repeatable.

The use of such sputtering targets is advantageous in that a large index (n) range from about 2.35 (x=0.05) to 1.6 (x=0.9) can be achieved in a dielectric oxide based thin film layer(s) without suffering significant absorption loss in the visible wavelength range. Moreover, another example advantage is that consistent optical properties (e.g., n and/or k of a resulting thin film) can be substantially predefined by setting x to a desired value during target fabrication. Yet another example advantage is that a high sputter-deposition rate can be achieved due to the partially oxidized phase (y less than 2.0) in the target. Further, yet another example advantage is that improved adhesion to an optional adjacent metal layer(s) (e.g., an Ag layer, or a NiCr layer), metal oxide layer, metal nitride layer, or metal oxynitride layer, can be achieved due to the formation of a silicide (Ti and Si) at the layer interface(s).

Certain example embodiments of this invention relate to a sputtering target of or including Ti₁₋ₓSiₓO_{y} and/or a method of making a coated article using such a sputtering target. In certain example embodiments, the target may be a rotatable magnetron sputtering target, a stationary planar target, or the like. In certain example embodiments, the Ti₁₋ₓSiₓO_{y} may be substoichiometric with respect to oxygen. In certain example embodiments of this invention, the target may be of or include Ti₁₋ₓSiₓO_{y} where x is from about 0.05 to 0.95 (more preferably from about 0.1 to 0.9, and even more preferably from about 0.2 to 0.8, and possibly from about 0.5 to 0.8) and y is from about 0.2 to 1.95 (more preferably from about 0.2 to 1.95, and even more preferably from about 0.2 to 1.90, and possibly from about 1.0 to 1.85). In certain example embodiments, y is no greater than about 1.95 or 1.90 in order to achieve desired conductivity to facilitate DC, pulsed DC, or middle frequency (e.g., <200 kHz) AC magnetron sputtering. In certain example embodiments, y is at least 0.2 in order to maintain a desired deposition rate of the film during sputtering without a significant absorption loss in the visible range during reactive sputtering.

The sputtering target may be sputtered in an atmosphere of or including one or more of Ar, O₂ and/or N₂ gas(es) in certain example embodiments of this invention. Other materials may be provided in the target in alternative example embodiments of this invention.

Such a target may be used to permit layers with tunable indices of refraction (n) to be consistently achieved by sputter deposition. By adjusting the Ti and Si amounts in the target (e.g., the Ti/Si ratio in the target itself), layers of or including TiSiOₓ (e.g., where x is from about 1.5 to 2.0) can be formed by sputter-deposition and can achieve consist desired index values (n). For example, the more Si in the target, the lower the index of refraction (n) value of the resulting sputter-deposited layer. Likewise, the more Ti in the target (and thus the less Si), the higher the index of refraction (n) value of the resulting sputter-deposited layer. Thus, an improved technique is provided to consistently form sputter-deposited layers having an index of refraction (n) in the range of from about 1.6 to 2.35. In particular, a technique is provided which permits layers to be sputter-deposited in a manner which allows a desired refraction index (n) value in this range to be consistently achievable. While gas flows may be adjusted to alter or tailor the index (n) value of the resulting layer, the primary way to adjust the index (n) value of the resulting layer is to adjust the Ti/Si ratio in the target itself.

The combination of Ti and Si in the target is advantageous in that Si and Ti form a suitable alloy. Since a ceramic target is used, including Ti and Si, the amounts of Ti and Si can be varied to allow the desired index (n) value to be obtained in the resulting layer. Moreover, the ceramic nature of the sputtering target is advantageous in that it permits higher sputtering rates to be achieved. The oxygen in the target is substoichiometric in certain example embodiments of this invention.

Instead of Si, Al may be used to replace the Si in the target and the resulting sputter-deposited layer in certain example alternative embodiments of this invention. As another alternative, Al may be added to Ti₁₋ₓSiₓO_{y} targets as an additional material in certain example alternative embodiments of this invention. Other materials such as Zr, V, Hf, Nb, Ce, Sb, Bi, Zn, Sn and Mg may be used instead of Al in each of these respects in still further example embodiments of this invention. Moreover, as will be appreciated herein, nitrogen gas may also be used in the sputtering process in order to enhance absorption in both the UV and the visible ranges if desired. The addition of one or more of these elements may be used to improve durability, UV absorption, and/or adhesion to adjacent layer(s) in different example embodiments of this invention. In certain example embodiments, it is possible to add extra element(s) to achieved desired properties such as adhesion, stress and/or UV absorption without significantly adversely affecting the desired optical index value through adjustment of the Ti/Si ratio for instance. For example, adding Sb may increase not only UV absorption, but also index. The index may be brought back to a desired value by adding extra Si if desired.

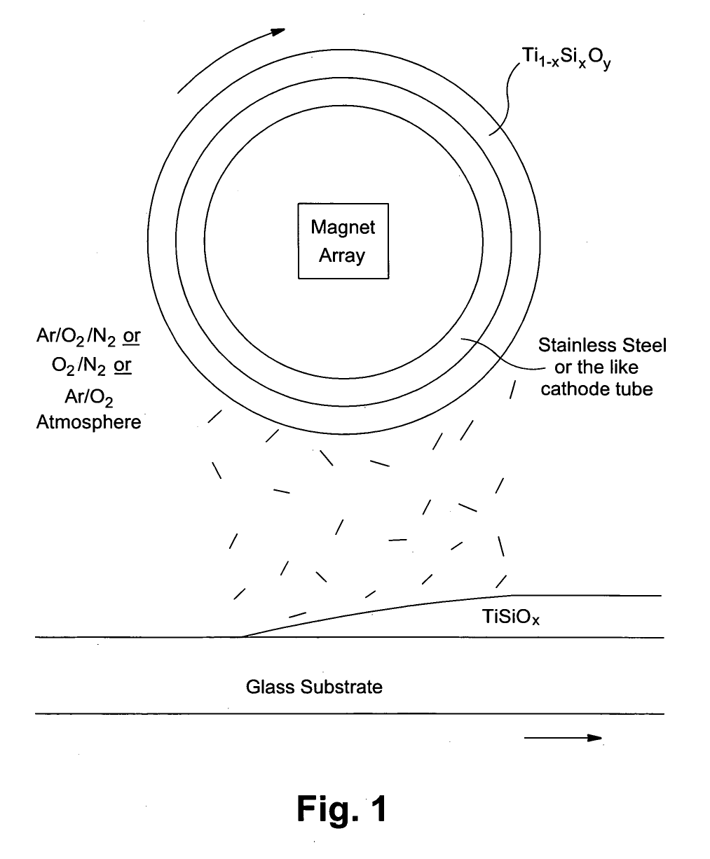

FIG. 1 is a cross sectional view of a sputtering target according to an example embodiment of this invention, being used in sputter-depositing a thin film layer on a substrate according to an example embodiment of this invention. The rotatable magnetron sputtering target shown in FIG. 1 includes a cathode tube within which is a stationary magnet bar array. The cathode tube is often made of stainless steel or some other conductive material. The target material (Ti₁₋ₓSiₓO_{y} in the FIG. 1 embodiment) is formed on the cathode tube by spraying, casting or pressing it onto the outer surface of the stainless steel cathode tube (optionally, a backing layer, which may be conductive, may be provided between the cathode tube and the target material layer). Each sputtering chamber in a sputtering apparatus includes one or more targets, and thus includes one or more of these cathode tubes. Different targets are used to sputter-deposit different layers of a multi-layer low-E or AR coating. For cylindrical rotatable magnetron sputtering targets, the cathode tube(s) may be held at a negative potential (e.g., −200 to −1500 V), and may be sputtered when rotating. When a target is rotating for example, due to the negative biased potential on the target, ions from the sputtering gas (e.g., argon, oxygen and/or nitrogen) discharge are accelerated into the target and dislodge, or sputter off, atoms of the target material. These atoms, in turn, together with the gas form the appropriate compound (e.g., TiSiOx) that is directed to the substrate in order to form a thin film or layer of the same (e.g., TiSiOₓ thin film shown in FIG. 1, where x may be about 2 in certain example instances, or may be slightly less than 2 in other example instances) on the substrate. The substrate may be a glass substrate as shown in FIG. 1 in certain example embodiments of this invention.

Sputter-deposited thin films of TiSiOx may be any suitable thickness in certain example embodiments of this invention. However, in certain example embodiments of this invention, the TiSiOx thin films may be sputter-deposited to a thickness on the substrate of from about 10 angstroms to 2.5 μm, more preferably from about 10 to 900 angstroms (Å), more preferably from about 50 to 800 angstroms, and most preferably from about 100 to 600 angstroms. Coated articles according to this invention may be used for any suitable purpose, but windows, fireplace glass, furniture table tops and the like are particularly preferred. In certain example embodiments of this invention, windows having coatings according to certain example embodiments of this invention may have a visible transmission of at least about 50%, more preferably of at least about 60%. Moreover, the sputter-deposited TiSiOx thin films are substantially transparent according to certain example embodiments of this invention.

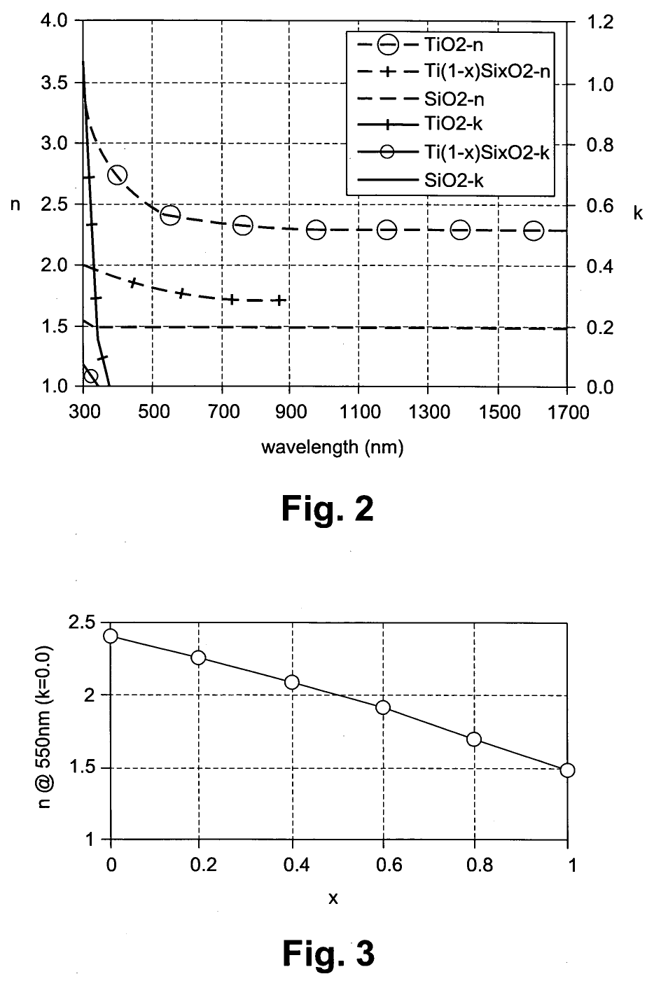

FIG. 2 is a graph illustrating optical properties (n and k) of Ti₁₋ₓSiₓO₂ thin film layers according to example embodiments of this invention (compared to TiO₂ and SiO₂ thin film layers). FIG. 2 illustrates that Ti₁₋ₓSiₓO₂ inclusive thin film layers made on a substrate (directly or indirectly on the substrate in different instances) have index of refraction (n) values between those of TiO₂ and SiO₂ thin film layers due to the presence of both titanium oxide and silicon oxide in the Ti₁₋ₓSiₓO₂ inclusive thin film layers. FIG. 3 is a graph illustrating that the refractive index (n) value of thin film Ti₁₋ₓSiₓO₂ layers can be varied as a function of different x values (i.e., changing the Ti/Si ratio in the target and thus in the sputter-deposited layer). In particular, FIG. 3 illustrates that the refractive index (n) value can be varied from about 1.6 to 2.35 in certain example embodiments of this invention, and can be varied from about 1.6 to about 1.9 in certain preferred example embodiments, as x is changed in the target.

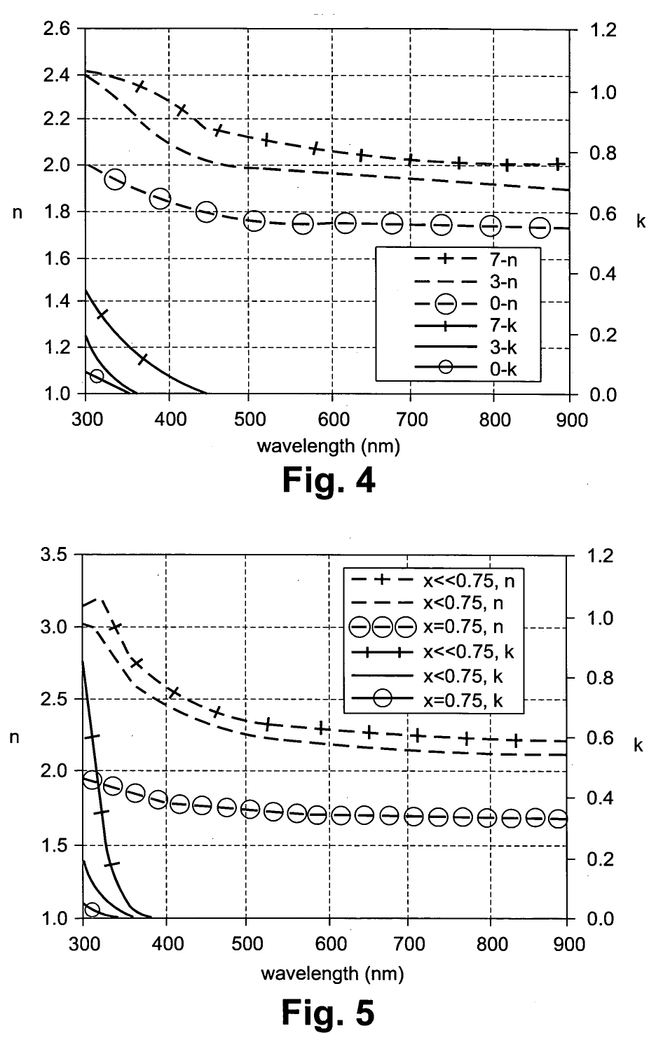

In certain example embodiments of this invention, the gas used in the sputtering chamber where the Ti₁₋ₓSiₓO_{y} target is present may be a mixture of argon (Ar) and oxygen (O₂) gases. This results in a sputter-deposited thin film layer of Ti₁₋ₓSiₓO₂ (if sufficient oxygen gas is used) on the glass substrate. However, it is possible to use other gas(es) as well. For example, a mixture of argon (Ar), oxygen (O₂) and nitrogen (N₂) gases may be used in the sputtering chamber in certain example embodiments of this invention. Different amounts of oxygen and nitrogen gases may be used in different example embodiments. It is also possible to use a mixture of Ar and N gas in the sputtering chamber(s) when sputtering the Ti₁₋ₓSiₓO_{y} target. It is also possible to use only argon, or only nitrogen, gas in the sputtering chamber(s) when sputtering the Ti₁₋ₓSiₓO_{y} target. FIG. 4 is a graph illustrating optical properties (n and k) of thin film layers of Ti₁₋ₓSiₓO_{2-y}N_{y} (where x=0.75) according to example embodiments of this invention, as a function of adjusting the oxygen and nitrogen gas flows in the sputtering chamber when sputtering the Ti₁₋ₓSiₓO_{y} target to form a layer of TiSiON. In FIG. 4, n and k of the resulting sputter-deposited layer are illustrated for different N₂/O₂ gas flow ratios of 0, 3 and 7, illustrating that an increase of nitrogen gas (and thus a reduction in oxygen gas in the sputtering chamber) in the sputtering process results in an increased index of refraction (n) value and absorption due to the increase in silicon nitride and titanium nitride in the resulting thin film layer. Accordingly, as the amount of nitrogen gas decreases (and thus oxygen gas amounts increase in the sputtering chamber), the refractive index (n) and absorption coefficient (k) of the layer decreases due to more titanium oxide and silicon oxide in the resulting layer.

FIG. 5 is a graph illustrating optical properties (n and k) of thin film layers of Ti₁₋ₓSiₓO_{2-y}N_{y} (using a N₂/O₂ gas flow ratio of 0.48 in the sputtering chamber where the Ti₁₋ₓSiₓO_{y} target is located), with varying x values. FIG. 5 illustrates that decreasing x (i.e., reducing the amount of Si compared to Ti in the target and thus in the sputter-deposited layer) results in an increase in refractive index (n) values and absorption of the resulting layer due to an increase in titanium oxide and titanium nitride in the sputter-deposited thin film layer on the substrate. It is noted that instead of, or in addition to, adding nitrogen gas to the sputtering chamber during the sputtering of the Ti₁₋ₓSiₓO_{y} target, other metallic element(s) can be added to the target to modify the thin film properties. Using metallic elements in the target tends to result in thin film properties that are more predictable and repeatable.

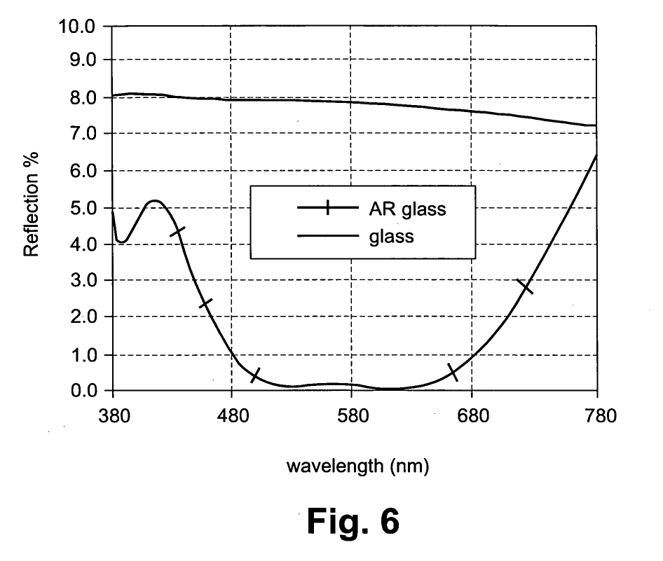

FIG. 6 is a graph illustrating the reflection %, as a function of wavelength, of coated article including a 3-layered AR coating on both sides of a 5 mm thick float glass substrate (soda lime silica glass); compared to reflection % of an uncoated 5 mm thick similar glass substrate. Each of the two AR coatings on the glass substrate were made up of, from the glass substrate outwardly, a 653 angstrom thick base layer of Ti_{0.28}Si_{0.72}O₂, then a 959 angstrom thick layer of Ti_{0.80}Si_{0.20}O₂, and then on top furthest from the glass substrate a 885 angstrom thick layer of SiO₂. Thus, the refractive index of the silicon oxide layer on top was the lowest, and that of the middle layer the highest. The refractive indices of the layers were 1.79, 2.25, and 1.46 for x=0.72, 0.20 and 1.00, respectively. Moreover, this AR coating improved adhesion among the different layers of the coating, and had a wide process window.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A target for use in sputter depositing a layer(s) on a substrate, the target comprising a target material comprising Ti₁₋ₓSiₓO_{y} where x is from about 0.05 to 0.95 and y is from about 0.2 to 1.95.

2. The target of claim 1, wherein x is from about 0.1 to 0.9, and y is from about 0.2 to 1.90.

3. The target of claim 1, wherein x is from about 0.2 to 0.8, and y is from about 1.0 to 1.85.

4. The target of claim 1, wherein the target material is supported by a conductive cathode tube.

5. The target of claim 4, wherein the target is a rotatable magnetron sputtering target, and one or more magnets is/are provided within the tube.

6. The target of claim 4, wherein a backing layer is provided between the target material and the cathode tube.

7. The target of claim 6, wherein the backing layer is conductive.

8. The target of claim 1, wherein the target material further comprises Al.

9. The target of claim 1, wherein the target material further comprises one or more of Zr, V, Hf, Nb, Ce, Sb, Bi, Zn, Sn and Mg.

10. The target of claim 1, wherein the target is a planar target.

11. A method of sputter-depositing a layer comprising silicon oxide and titanium oxide on a substrate, the method comprising:
providing a target comprising Ti₁₋ₓSiₓO_{y} where x is from about 0.05 to 0.95 and y is from about 0.2 to 1.95, and
flowing argon and/or oxygen gas in a chamber where the target is located, so as to cause the layer comprising silicon oxide and titanium oxide to be formed on the substrate.

12. The method of claim 11, wherein the substrate is a glass substrate.

13. The method of claim 11, wherein the layer is formed directly on and contacting the substrate.

14. The method of claim 11, wherein at least one additional layer is provided between the substrate and the layer formed using the target.

15. The method of claim 11, wherein x is from about 0.1 to 0.9, and y is from about 0.2 to 1.90.

16. The method of claim 11, wherein x is from about 0.2 to 0.8, and y is from about 1.0 to 1.85.

17. The method of claim 11, wherein the target includes target material comprising Ti₁₋ₓSiₓO_{y} which is supported by a conductive tube, and wherein the target is rotated during sputtering thereof.

18. The method of claim 17, wherein the target is a rotatable magnetron sputtering target, and one or more magnets is/are provided within the conductive tube, and wherein the magnets do not move during rotation of the tube and the target material.

19. The method of claim 17, wherein a backing layer is provided between the target material and the tube.

20. The method of claim 11, wherein the target further comprises Al.

21. The method of claim 11, wherein the target further comprises one or more of Al, Zr, V, Hf, Nb, Ce, Sb, Bi, Zn, Sn and Mg.

22. The method of claim 11, wherein the target is a planar target.

23. A target for use in sputter depositing a layer(s) on a substrate, the target comprising a target material comprising titanium, silicon and oxygen, so as to be a ceramic target.
